(19) United States
(12) Patent Application Publication
(10) Pub. No.: US 2026/0150291 A1
(43) Pub. Date: May 28, 2026

(54) VERTICAL NON-VOLATILE MEMORY DEVICE, ELECTRONIC APPARATUS INCLUDING THE SAME, AND METHOD OF MANUFACTURING VERTICAL NON-VOLATILE MEMORY DEVICE

(71) Applicant: Samsung Electronics Co., Ltd., Suwon-si (KR)

(72) Inventors: Hoseok HEO, Suwon-si (KR); Minhyun LEE, Suwon-si (KR); Seokhoon CHOI, Suwon-si (KR); Jinjoo PARK, Suwon-si (KR); Seonghun JANG, Suwon-si (KR)

(73) Assignee: Samsung Electronics Co., Ltd., Suwon-si (KR)

(21) Appl. No.: 19/375,458

(22) Filed: Oct. 31, 2025

(30) Foreign Application Priority Data
Nov. 26, 2024 (KR) 10-2024-0171451

(51) Int. Cl. H10B 43/27; G11C 16/04; H10B 43/10; H10B 43/35; H10D 30/01; H10D 30/69; H10D 64/68

(52) U.S. Cl. CPC H10B 43/27; G11C 16/0483; H10B 43/10; H10B 43/35; H10D 30/0413; H10D 30/693; H10D 64/685; H10D 64/691

(57) ABSTRACT

Provided is a vertical non-volatile memory device including a plurality of cell strings. Each of the plurality of cell strings may include a channel layer, a charge tunneling layer, a charge trap layer, and a charge blocking layer, which may be sequentially arranged in a horizontal direction perpendicular to a longitudinal direction. The charge trap layer may include a film having a plurality of nanostructures dispersed in a matrix. A dielectric permittivity of the plurality of nanostructures may be higher than a dielectric permittivity of the matrix.

### CROSS-REFERENCE TO RELATED APPLICATION

This application is based on and claims priority under 35 U.S.C. § 119 to Korean Patent Application No. 10-2024-0171451, filed on Nov. 26, 2024, in the Korean Intellectual Property Office, the disclosure of which is incorporated by reference herein in its entirety.

### BACKGROUND

### 1. Field

The disclosure relates to a vertical non-volatile memory device, an electronic device including the vertical non-volatile memory device, and/or a method of manufacturing the vertical non-volatile memory device.

### 2. Description of the Related Art

A non-volatile memory device includes a plurality of memory cells that may use again stored information when power is supplied, as they retain information even when power supply is stopped. The non-volatile memory device may be broadly applied to a mobile phone, a digital camera, a personal information terminal (e.g., a personal digital assistance (PDA)), a mobile computer device, etc.

Recently, as it is requested for a memory device to have a high integrity and lower power characteristic, a vertical NAND (VNAND) flash memory device is being developed. In the VNAND flash memory device, charge migration between memory cells may occur due to an increase in the number of stacked layers of a memory cell and a height decrease in the stacked layers, and the charge migration may degrade a charge retention characteristic of the memory cell.

### SUMMARY

Provided is a vertical non-volatile memory device in which a charge retention characteristic of a memory cell may be improved.

Additional aspects will be set forth in part in the description which follows and, in part, will be apparent from the description, or may be learned by practice of the presented embodiments of the disclosure.

According to an example embodiment of the disclosure, a vertical non-volatile memory device may include a plurality of cell strings. Each of the plurality of cell strings may include a channel layer, a charge tunneling layer, a charge trap layer, and a charge blocking layer, which may be sequentially arranged in a horizontal direction. The horizontal direction may be perpendicular to a longitudinal direction. Each of the plurality of cell strings may further include a plurality of gate electrodes, which may be arranged in the longitudinal direction on an outer side of the charge blocking layer, and a plurality of separation layers isolating the plurality of gate electrodes in the longitudinal direction. The charge trap layer may include a film having a plurality of nanostructures dispersed in a matrix. The charge trap layer may include a first metal oxide dielectric and a second metal oxide dielectric. A dielectric permittivity of the first metal oxide dielectric may be greater than a dielectric permittivity of the second metal oxide dielectric. A composition ratio of the first metal oxide dielectric of the plurality of nanostructures may be greater than a composition ratio of the first metal oxide dielectric of the matrix.

In some embodiments, the plurality of nanostructures may be apart from each other.

In some embodiments, the plurality of nanostructures may be apart from the charge tunneling layer and the charge blocking layer by the matrix.

In some embodiments, the plurality of nanostructures may define an insertion layer, and the insertion layer may be apart from the charge tunneling layer and the charge blocking layer by the matrix.

In some embodiments, the composition ratio of the first metal oxide dielectric of the plurality of nanostructures may be greater than 50% and less than 100%.

In some embodiments, the composition ratio of the first metal oxide dielectric of the plurality of nanostructures may be equal to or greater than 80% and less than 100%.

In some embodiments, a crystallization threshold energy of the first metal oxide dielectric may be lower than a crystallization threshold energy of the second metal oxide dielectric.

In some embodiments, a conduction band offset of the second metal oxide dielectric with respect to the charge tunneling layer may be greater than a conduction band offset of the first metal oxide dielectric with respect to the charge tunneling layer.

In some embodiments, the first metal oxide dielectric may include hafnium oxide (HfO), zirconium oxide (ZrO), lanthanum oxide (LaO), gallium oxide (GaO), yttrium oxide (YO), or titanium oxide (TiO).

In some embodiments, the second metal oxide dielectric may include aluminum oxide (AlO), tantalum oxide (TaO), or silicon oxide (SiO).

According to an example embodiment of the disclosure, a method of manufacturing a memory device may include alternately stacking a first layer and a second layer on a substrate; forming a channel hole penetrating through the first layer and the second layer; and forming a charge blocking layer, a charge trap layer, a charge tunneling layer, and a channel layer sequentially from an inner wall of the channel hole. The forming the charge trap layer may include forming, on an inner wall of the charge blocking layer, a combination layer in which a first metal oxide dielectric having a relatively high dielectric permittivity and a second metal oxide dielectric having a relatively low dielectric permittivity are mixed; and performing a heat treatment on the combination layer.

The heat treatment on the combination layer may form a plurality of nanostructures in matrix. A composition ratio of the second metal oxide dielectric may be higher in the matrix than in the plurality of nanostructures. A composition ratio of the first metal oxide dielectric may be higher in the plurality of nanostructures than in the matrix.

In some embodiments, the plurality of nanostructures may be apart from the charge tunneling layer and the charge blocking layer by the matrix.

In some embodiments, the composition ratio of the first metal oxide dielectric of the plurality of nanostructures may be greater than 50% and less than 100%.

In some embodiments, the composition ratio of the first metal oxide dielectric of the plurality of nanostructures may be equal to or greater than 80% and less than 100%.

In some embodiments, a crystallization threshold energy of the first metal oxide dielectric may be lower than a crystallization threshold energy of the second metal oxide dielectric.

In some embodiments, a conduction band offset of the second metal oxide dielectric with respect to the charge tunneling layer may be greater than a conduction band offset of the first metal oxide dielectric with respect to the charge tunneling layer.

In some embodiments, the first metal oxide dielectric may include hafnium oxide (HfO), zirconium oxide (ZrO), lanthanum oxide (LaO), gallium oxide (GaO), yttrium oxide (YO), or titanium oxide (TiO).

In some embodiments, the second metal oxide dielectric may include aluminum oxide (AlO), tantalum oxide (TaO), or silicon oxide (SiO).

According to an example embodiment of the disclosure, an electronic device may include a memory including the aforementioned vertical non-volatile memory device, and a memory controller configured to control the memory for data reading from the memory and/or data writing to the memory.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a vertical non-volatile memory device according to an embodiment;

FIG. 2 is a cross-sectional view of the vertical non-volatile memory device, taken along line A-A′ of FIG. 1;

FIG. 3 is a magnified view of D1 portion of FIG. 2;

FIG. 4 illustrates a trap density in a charge trap layer;

FIG. 5 illustrates a result of simulation in which a charge retention characteristic of a memory cell according to a composition ratio of hafnium when the memory cell is modeled as a transistor and a charge trap layer is formed of hafnium-aluminum oxide is compared with a case in which the charge trap layer is formed of silicon nitride (SiN);

FIG. 6 is a schematic cross-sectional view of a vertical non-volatile memory device according to an embodiment;

FIG. 7 is a magnified view of D2 portion of FIG. 6;

FIG. 8 illustrates a circuit diagram including a vertical non-volatile memory device according to an embodiment;

FIGS. 9A to 9J illustrate an embodiment of a method of manufacturing a vertical non-volatile memory device;

FIG. 10 is a schematic block diagram of a display driver integrated circuit (DDI) and a display device including the DDI, according to an embodiment;

FIG. 11 is a block diagram illustrating an electronic device according to an embodiment;

FIG. 12 is a block diagram of an electronic device according to an embodiment;

FIG. 13 is a conceptual diagram schematically illustrating device architecture applicable to an electronic device according to an embodiment; and

FIG. 14 is a conceptual diagram schematically illustrating device architecture applicable to an electronic device according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

Hereinafter, with reference to the attached drawings, a vertical non-volatile memory device and an electronic device including the same according to various embodiments will now be described in detail. In the drawings, the same reference numerals denote the same elements and sizes of elements may be exaggerated for clarity. While terms “first” and “second” are used to describe various elements, it is obvious that the elements are not limited to the terms “first” and “second”. The terms “first” and “second” are used only to distinguish between each of elements.

As used herein, the singular forms may include the plural forms as well, unless the context clearly indicates otherwise. Also, when a part “includes” or “comprises” an element, unless there is a particular description contrary thereto, the part can further include other elements, not excluding the other elements. In the drawings, sizes or thicknesses of elements may be exaggerated for clarity. When it is described that a preset material layer is provided on a substrate or another layer, the material layer may directly contact the substrate or the other layer, or an intervening layer may be provided therebetween. In embodiments below, a material included in each layer is merely an example, and thus, other materials may be used.

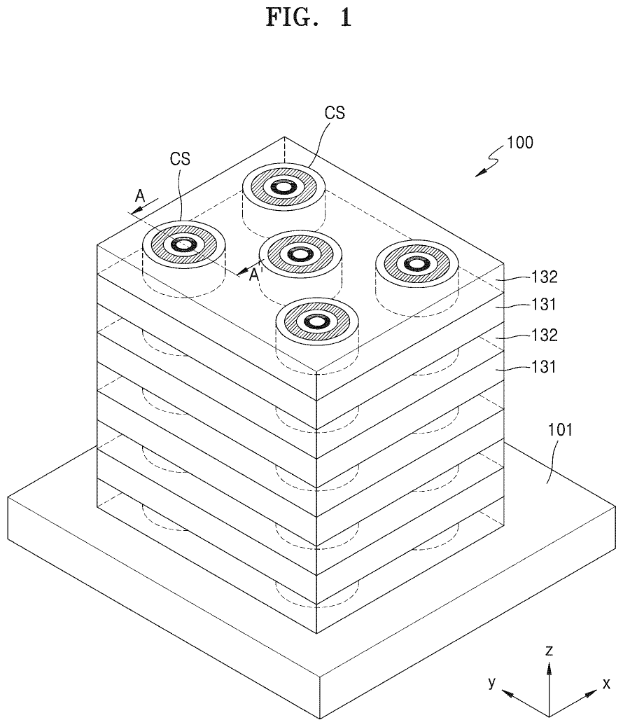

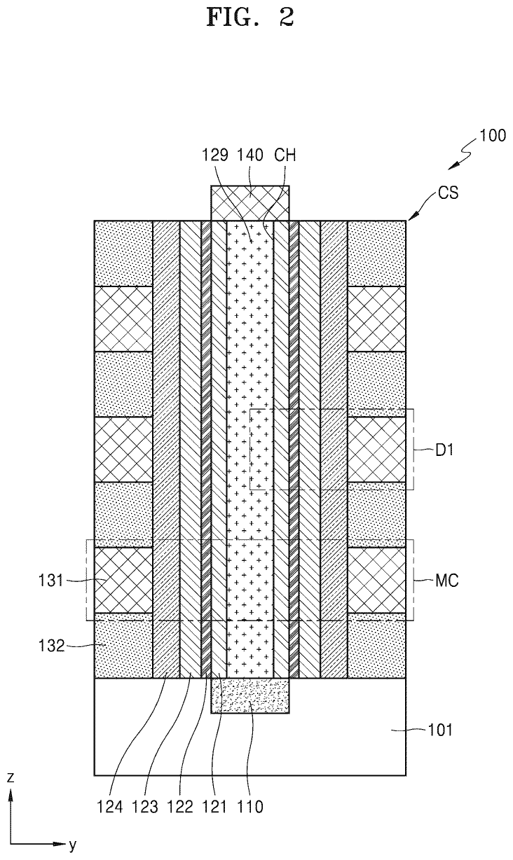

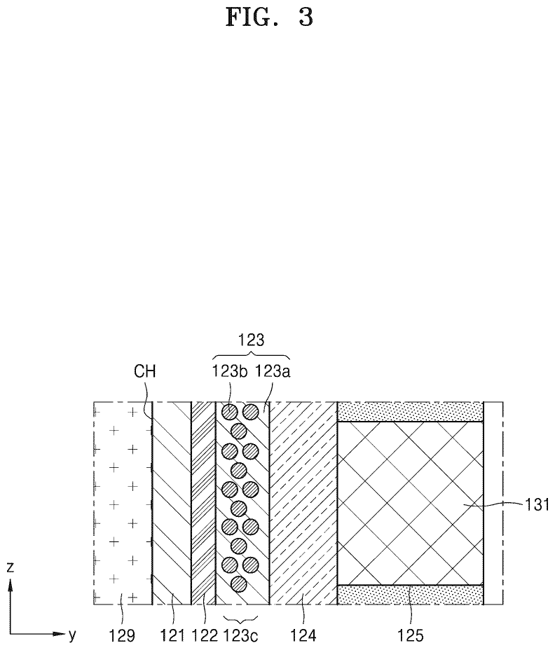

FIG. 1 is a schematic perspective view of a vertical non-volatile memory device 100 according to an embodiment. FIG. 2 is a cross-sectional view of the vertical non-volatile memory device 100, taken along line A-A′ of FIG. 1. FIG. 3 is a magnified view of D1 portion of FIG. 2.

Referring to FIG. 1, the vertical non-volatile memory device 100 (also referred to as the memory device 100) may include a plurality of cell strings CS arranged on a substrate 101. The plurality of cell strings CS extend in a longitudinal direction (z-axis direction in FIG. 1) that is a direction perpendicular to the substrate 101. The plurality of cell strings CS may be arranged in various forms on the substrate 101. A gate electrode 131 and a separation layer 132 may be alternately stacked on the substrate 101. Each of the plurality of cell strings CS may have a channel hole CH penetrating through a stack assembly of the gate electrode 131 and the separation layer 132 in the longitudinal direction (z). The channel hole CH may be formed to have a round cross-section. However, a cross-section shape of the channel hole CH is not limited thereto. A region of each cell string CS which excludes the gate electrode 131 and the separation layer 132 may have a cylindrical shell shape structure in which a plurality of material layers are stacked in horizontal directions (x, y) perpendicular to the longitudinal direction (z), outward from the channel hole CH. The plurality of material layers in the cylindrical shell shape form a memory cell MC. For example, each cell string CS includes a plurality of memory cells MC arranged in the z-axis direction. Some of the plurality of material layers forming each memory cell MC are isolated in the z-axis direction from a corresponding material layer of another memory cell MC, due to the separation layer 132. However, a structure of each cell string CS is not limited thereto, and may have a different shape and a different structure.

The substrate 101 may include, but is not limited to, a single crystal silicon substrate, a compound semiconductor substrate, or a silicon on insulator (SOI). Also, the substrate 101 may further include an impurity-doped region, an electronic device such as a transistor, or a periphery circuit selecting and controlling memory cells for storing data.

Referring to FIGS. 2 and 3, each of the plurality of cell strings CS may include the plurality of memory cells MC stacked in the direction (the z-axis direction) perpendicular to the substrate 101. Each memory cell MC may be a basic unit cell that writes and erases data.

Each cell string CS may include a channel layer 121, a charge tunneling layer 122, a charge trap layer 123, a charge blocking layer 124, and a plurality of gate electrodes 131. The plurality of gate electrodes 131 are isolated from each other in the longitudinal direction (z) due to a plurality of separation layers 132. The plurality of gate electrodes 131 face the channel layer 121, the charge tunneling layer 122, the charge trap layer 123, and the charge blocking layer 124 in a horizontal direction. Each memory cell MC is formed by regions of the channel layer 121, the charge tunneling layer 122, the charge trap layer 123, and the charge blocking layer 124 which face each gate electrode 131. In each cell string CS according to an embodiment, the plurality of memory cells MC share the channel layer 121, the charge tunneling layer 122, the charge trap layer 123, and the charge blocking layer 124.

The charge tunneling layer 122 is arranged on the outer side of the channel layer 121 in the horizontal direction perpendicular to the longitudinal direction (z-axis direction). The charge tunneling layer 122 extends in the longitudinal direction (z-axis direction) by surrounding an outer circumferential surface of the channel layer 121 in the horizontal direction. The charge trap layer 123 is arranged on the outer side of the charge tunneling layer 122 in the horizontal direction. The charge trap layer 123 extends in the longitudinal direction (z-axis direction) by surrounding an outer circumferential surface of the charge tunneling layer 122 in the horizontal direction. The charge blocking layer 124 is arranged on the outer side of the charge trap layer 123 in the horizontal direction. The charge blocking layer 124 extends in the longitudinal direction (z) by surrounding the charge trap layer 123. The plurality of gate electrodes 131 are arranged apart from each other in the longitudinal direction (z) on the outer side of the charge blocking layer 124 in the horizontal direction, and are isolated from each other in the longitudinal direction (z) by the plurality of separation layers 132.

A source electrode 110 and a drain electrode 140 are respectively arranged in both sides of the channel layer 121 in the longitudinal direction (z). The source electrode 110 may be commonly connected to the plurality of cell strings CS. When a preset voltage is applied to each gate electrode 131 of each memory cell MC, a channel may be generated in an inner region of the channel layer 121 facing each gate electrode 131, and charges flowing between the source electrode 110 and the drain electrode 140 may pass through the charge tunneling layer 122 and may be trapped in the charge trap layer 123, so that information may be stored.

The channel layer 121 may include a semiconductor material. The channel layer 121 may include Si, Ge, SiGe, a group III-V semiconductor material, etc. Also, for example, the channel layer 121 may include an oxide semiconductor, a nitride semiconductor, an oxynitride semiconductor, a two-dimensional (2D) semiconductor material, a quantum dot (QD), or an organic semiconductor. In this regard, the oxide semiconductor may include InGaZnO, etc. For example, the 2D semiconductor material may include transition metal dichalcogenide (TMD) or graphene, and the QD may include a colloidal QD, a nanocrystal structure, etc. The 2D semiconductor material may indicate a semiconductor material having a 2D crystal structure, and may have a monolayer structure or a multilayer structure. The 2D semiconductor material is a material that may be applied to various devices as the material has an excellent electrical property and maintains high mobility without a significant change in its characteristic even when a thickness thereof is decreased to the nanoscale. Each of layers constituting the 2D semiconductor material may have an atomic level thickness. The channel layer 121 may include 1 to 10 layers of the 2D semiconductor material.

For example, the 2D semiconductor material may include at least one of graphene, black phosphorous, and TMD. The graphene is a material in which carbon atoms are two-dimensionally combined to have a hexagonal honeycomb structure, and which has high electrical mobility and excellent heat property, is chemically stable, and has a large surface area, compared to silicon (Si). The black phosphorous is a material in which black phosphorous atoms are two-dimensionally combined.

For example, the TMD may be expressed as MX₂, where M indicates transition metal and X indicates a chalcogen element. For example, M may include molybdenum (Mo), tungsten (W), niobium (Nb), vanadium (V), tantalum (Ta), titanium (Ti), zirconium (Zr), hafnium (Hf), technetium (Tc), or rhenium (Re), and X may include sulfur(S), selenium (Se), or tellurium (Te). Therefore, for example, the TMD may include MoS₂, MoSe₂, MoTe₂, WS₂, WSe₂, WTe₂, ZrS₂, ZrSe₂, HfS₂, HfSe₂, NbSe₂, ReSe₂, etc.

Alternatively, the 2D semiconductor material may include CuS that is a combination of copper (Cu) that is transition metal and S that is a chalcogen element. The 2D semiconductor material may be a chalcogenide material including non-transition metal. The non-transition metal may include gallium (Ga), indium (In), tin (Sn), germanium (Ge), lead (Pb), etc. In this case, the 2D semiconductor material may include a combination of transition metal including Ga, In, Sn, Ge, Pb, etc. and a chalcogen element including S, Se, Te, etc. For example, the 2D semiconductor material may include SnSe₂, GaS, GaSe, GaTe, GeSe, In₂Se₃, InSnS₂, etc. However, materials described above are merely an example, and thus, other materials may be used as the 2D semiconductor material.

The channel layer 121 may further include a dopant. In this regard, the dopant may include a p-type dopant or an n-type dopant. For example, the p-type dopant may include a group III element including boron (B), aluminum (Al), Ga, In, etc., and the n-type dopant may include a group V element including phosphorus (P), arsenic (As), antimony (Sb), etc.

In the present embodiment, the channel layer 121 has a cylindrical shape.

Therefore, the channel hole CH is arranged in the channel layer 121. A pillar 129 may be filled in the channel hole CH. For example, the pillar 129 may include silicon oxide (SiO₂) or air, but the disclosure is not limited thereto.

The charge tunneling layer 122 may be arranged between the channel layer 121 and the charge trap layer 123, in which charge tunneling occurs between the channel layer 121 and the charge trap layer 123, and may include, but is not limited to, silicon oxide or metal oxide. For example, in the present embodiment, the charge tunneling layer 122 includes silicon oxide.

The charge trap layer 123 may store flowed charges. Charges (e.g., electrons) in the channel layer 121 may be flowed into the charge trap layer 123, due to a tunneling effect, etc. The charges flowed into the charge trap layer 123 may be trapped in the charge trap layer 123. In the present embodiment, the charge trap layer 123 includes a matrix 123a forming a thin film (e.g., a thin film having a thickness of less than or equal to 100 nm, less than or equal to 50 nm, less than or equal to 25 nm and the like), and nanostructures 123b dispersed in the matrix 123a. The nanostructures 123b may be apart from each other. The nanostructures 123b may not be directly contact the charge tunneling layer 122 and the charge blocking layer 124 which are adjacent thereto. Due to the matrix 123a, the nanostructures 123b may be apart from the adjacent charge tunneling layer 122 and adjacent the charge blocking layer 124. In other words, the nanostructures 123b form an insertion layer 123c inserted into the matrix 123a, which is apart from the charge tunneling layer 122 and the charge blocking layer 124.

The charge trap layer 123 may include a metal oxide dielectric. The charge trap layer 123 may include a ternary metal oxide dielectric including a first metal oxide dielectric and a second metal oxide dielectric. The charge trap layer 123 may be an amorphous combination of the first metal oxide dielectric and the second metal oxide dielectric. A dielectric permittivity of the first metal oxide dielectric may be greater than a dielectric permittivity of the second metal oxide dielectric. A crystallization threshold energy of the first metal oxide dielectric may be lower than that of the second metal oxide dielectric. A conduction band offset (CBO) of the second metal oxide dielectric with respect to the charge tunneling layer 122 may be greater than a CBO of the first metal oxide dielectric with respect to the charge tunneling layer 122. Also, a valance band offset (VBO) of the second metal oxide dielectric with respect to the charge tunneling layer 122 may be greater than a VBO of the first metal oxide dielectric with respect to the charge tunneling layer 122.

For example, the first metal oxide dielectric may include hafnium oxide (HfO), zirconium oxide (ZrO), lanthanum oxide (LaO), gallium oxide (GaO), yttrium oxide (YO), or titanium oxide (TiO). For example, the second metal oxide dielectric may include aluminum oxide (AlO), tantalum oxide (TaO), or silicon oxide (SiO). The matrix 123a and the nanostructures 123b dispersed in the matrix 123a are formed by the ternary metal oxide dielectric. The charge trap layer 123 in the aforementioned form may be formed by a spinodal decomposition and a nucleation growth by performing a heat treatment on the combination of the first metal oxide dielectric and the second metal oxide dielectric.

The matrix 123a and the nanostructures 123b may differ in composition ratios of the first metal oxide dielectric and the second metal oxide dielectric. For example, the nanostructures 123b may have a higher composition ratio of the first metal oxide dielectric and the matrix 123a may have a higher composition ratio of the second metal oxide dielectric. Therefore, a dielectric permittivity of the nanostructures 123b may be higher than a dielectric permittivity of the matrix 123a. Also, a CBO of the matrix 123a with respect to the charge tunneling layer 122 may be greater than a CBO of the nanostructures 123b (e.g., the insertion layer 123c) with respect to the charge tunneling layer 122. Also, a VBO of the matrix 123a with respect to the charge tunneling layer 122 may be greater than a VBO of the nanostructures 123b (e.g., the insertion layer 123c) with respect to the charge tunneling layer 122. The matrix 123a may have a relatively high CBO and VBO and may have an excellent blocking characteristic with respect to charge migration.

For example, when it is assumed that the first metal forming the first metal oxide dielectric may be referred to as A and the second metal forming the second metal oxide dielectric may be referred to as B, the first metal oxide dielectric may be expressed as AO, the second metal oxide dielectric may be expressed as BO, and a combination thereof may be expressed as A_{R}B_{1-R}O. The matrix 123a may have a BO-rich state, in which a composition ratio of the second metal oxide dielectric may be relatively high (e.g., a composition ratio of the first metal oxide dielectric may be lower than the nanostructures 123b). The nanostructures 123b may have an AO-rich state in which a composition ratio of the first metal oxide dielectric may be higher than the matrix 123a, for example the composition ratio of the first metal oxide dielectric may be greater than 50% and less than 100%. A composition of the matrix 123a may satisfy A_{R}B_{1-R}O, where 0.5>R, A may be the first metal oxide dielectric, and B may be the second metal oxide dielectric. In some embodiments, composition of the matrix 123a may satisfy A_{R}B_{1-R}O, where 0.2>R, A may be the first metal oxide dielectric, and B may be the second metal oxide dielectric. In some embodiments, a composition of the nanostructures 123b may satisfy A_{R}B_{1-R}O, where 0.5<R<1, A may be the first metal oxide dielectric, and B may be the second metal oxide dielectric. For example, in some embodiments, a composition of the nanostructures 123b may satisfy A_{R}B_{1-R}O, where 0.8<R<1, where A may be the first metal oxide dielectric, and B may be the second metal oxide dielectric.

The nanostructures 123b may have various shapes including a round shape, an oval shape, a disc shape, a rod shape, an atypical shape, etc. The charge trap layer 123 may have an entirely amorphous structure. The first metal oxide dielectric having the low crystallization threshold energy provides a thermal stability by allowing the charge trap layer 123 to be entirely amorphous in a high temperature by suppressing crystallization of the charge trap layer 123 in a heat treatment process of forming the charge trap layer 123. The matrix 123a may have an amorphous structure, and the nanostructures 123b may have a crystalline or amorphous structure. When the nanostructures 123b have the crystalline structure, the nanostructures 123b may be referred to as nano crystals.

The charge blocking layer 124 may perform a barrier function for blocking charge migration between the charge trap layer 123 and each gate electrode 131. One side of the charge blocking layer 124 may contact the charge trap layer 123, and the other side of the charge blocking layer 124 may contact each gate electrode 131. The charge blocking layer 124 may include, but is not limited to, silicon oxide, metal oxide, or metal nitride. The charge blocking layer 124 may include at least one of AlO, magnesium oxide (MgO), aluminum nitride (AlN), and gallium nitride (GaN).

Each gate electrode 131 may control a region of the channel layer 121 corresponding thereto. A word line may be electrically connected to each gate electrode 131. Each gate electrode 131 may include a metal material having an excellent electric conductivity, conductive oxide, metal nitride, silicon doped with impurities, a 2D conductive material, etc. The metal material may include gold (Au), titanium (Ti), titanium nitride (TiN), tantalum nitride (TaN), tungsten (W), molybdenum (Mo), tungsten nitride (WN), platinum (Pt), niobium (Nb), niobium nitride (NbN) or nickel (Ni), or any arbitrary combination thereof. The conductive oxide may include indium tin oxide (ITO), indium zinc oxide (IZO), etc. However, this is merely an example, and each gate electrode 131 may include various other materials.

The plurality of separation layers 132 function as spacers for isolating the plurality of gate electrodes 131 from each other in the longitudinal direction (z). For example, the plurality of separation layers 132 may include, but is not limited thereto, silicon oxide, silicon nitride, etc. In the present embodiment, each separation layer 132 includes silicon oxide.

A reliability factor essentially requested for a vertical non-volatile memory device is retention of data, e.g., a characteristic capable of storing charges in the charge trap layer 123 for a long time. The vertical non-volatile memory device has a structure in which the memory cells MCs are connected in a vertical direction, e.g., the longitudinal direction (z). When information is stored, charges are diffused in the longitudinal direction (z) and are migrated to an adjacent memory cell MC, such that an operation of the adjacent memory cell MC may be affected. When a distance between the plurality of memory cells MC is decreased to increase a memory density in the vertical non-volatile memory device having a structure in which the plurality of memory cells MC in one cell string CS share the charge trap layer 123, e.g., the charge trap layer 123 extends to have the same length as the channel layer 121, charge migration between the plurality of memory cells MC may occur, and thus, a charge retention characteristic may deteriorate.

In a direction perpendicular to the charge trap layer 123, e.g., the x-axis direction and/or the y-direction, charges may be migrated from the charge trap layer 123 to the charge tunneling layer 122 via trap-assisted tunneling or thermal emission. A level of charge migration may be determined according to a CBO at an interface between the charge trap layer 123 and the charge tunneling layer 122.

In a direction parallel to the charge trap layer 123, e.g., in the longitudinal direction (z), charge migration may occur due to lateral migration according to a gradient of a charge density. The charge migration in the direction parallel to the charge trap layer 123 may be dominated by Poole-Frenkel tunneling. A current density by Poole-Frenkel tunneling may be expressed as Poole-Frenkel Conduction Equation (equation 1) below.

$$J = q μ {N}_{c} E exp ( \frac{- \text{?} ( {E}_{T} - \sqrt{\text{?} E / πε )}}{kT} ) \qquad ( equation 1 )$$

$$\text{?} \text{indicates text missing or illegible when filed}$$

(J: current Density, q: electronic charge, μ: carrier mobility N_{c}: density of states in conduction band, E: electric field, E_{T}: trap energy, ε: permittivity, k: Boltzmann constant, T: temperature)

The charge migration in the direction parallel to the charge trap layer 123 due to Poole-Frenkel tunneling may be determined according to a trap energy E_{T} and a trap density N_{T}. The trap energy indicates a voltage barrier that an electron has to cross to be migrated from one atom to another atom in a material. That is, the trap energy indicates a depth of a trap state with respect to conduction Band Minimum (CBM) of a material. The trap density indicates the number of trapped charges per unit volume. The trap density may be calculated by using a charge pumping method. A charge retention characteristic in the direction parallel to the charge trap layer 123 may be improved by high trap energy and high trap density.

In the present embodiment, the charge trap layer 123 includes the first metal oxide dielectric having a dielectric permittivity higher than that of the second metal oxide dielectric. Therefore, compared to a case in which only second metal oxide is applied, a dielectric permittivity of the entire charge trap layer 123 may be increased and/or capacitance may be improved, so that a memory window may be enhanced.

In the present embodiment, the charge trap layer 123 includes the nanostructures 123b dispersed in the matrix 123a, and the nanostructures 123b form the insertion layer 123c buried in the matrix 123a. The nanostructures 123b are apart from each other, and thus, function as independent charge trap media. Charges flowed into the charge trap layer 123 from the channel layer 121 via the charge tunneling layer 122 are trapped in each nanostructure 123b. In the nanostructures 123b, content of the first metal oxide dielectric having a relatively high dielectric permittivity is higher than the matrix 123a. That is, the nanostructures 123b have an AO-rich state. A dielectric permittivity of the nanostructures 123b is higher than a dielectric permittivity of the matrix 123a. The insertion layer 123c formed by the nanostructures 123b provides a new charge storage defect form, so that a trap density of the nanostructures 123b may be improved. Therefore, charges are mainly trapped in the nanostructures 123b, so that a trap density of the nanostructures 123b is higher than a trap density of the matrix 123a.

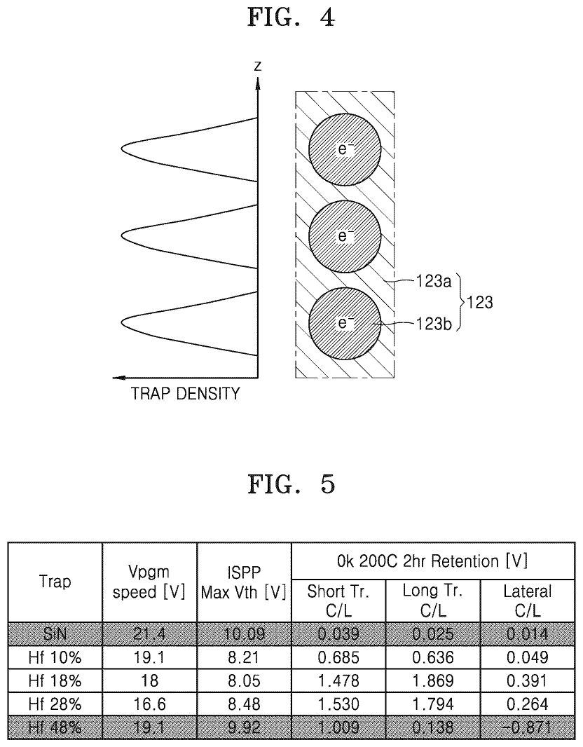

In order for charges to be laterally migrated in the longitudinal direction (z) of the charge trap layer 123, the charges have to be migrated in the longitudinal direction (z) along the nanostructures 123b. FIG. 4 illustrates a trap density in the charge trap layer 123. Referring to FIG. 4, charges, e.g., electrons, are trapped in the nanostructures 123b, and are barely trapped between the nanostructures 123b that are apart from each other. Therefore, a trap density of the nanostructures 123b is significantly higher than the matrix 123a, and a trap density of the charge trap layer 123 in the longitudinal direction (z) is discontinuous, according to arrangements of the nanostructures 123b. As the nanostructures 123b having a high trap density are spatially apart from each other, it is difficult for charges to be migrated between two adjacent nanostructures 123b. Therefore, trap-assisted conduction is limited and/or suppressed, such that lateral migration of charges may be decreased. The matrix 123a arranged between the nanostructures 123b functions as a barrier with respect to lateral migration of charges of the charge trap layer 123 in the longitudinal direction (z), and thus, lateral migration of charges may be further decreased.

Also, as the matrix 123a is arranged between the nanostructures 123b in which charges are trapped and between the nanostructures 123b and the charge tunneling layer 122, the matrix 123a functions as a barrier with respect to migration of charges from the charge trap layer 123 to the charge tunneling layer 122 via trap-assisted tunneling or thermal emission. Therefore, it is possible to decrease or prevent charges trapped in the nanostructures 123b from being migrated in a direction perpendicular to the charge trap layer 123, e.g., the x-axis direction or the y-axis direction.

When crystallization occurs in a heat treatment process of forming the charge trap layer 123, a disorderly grain boundary (GB) may be formed, and charges may be leaked along the GB. The first metal oxide dielectric having the low crystallization threshold energy suppresses crystallization of the charge trap layer 123 in the heat treatment process of forming the charge trap layer 123, and thus, provides thermal stability to allow the charge trap layer 123 to wholly maintain an amorphous state even in a high temperature.

FIG. 5 illustrates a result of simulation in which a charge retention characteristic of a memory cell MC according to a composition ratio of hafnium when the memory cell MC is modeled as a transistor and a charge trap layer is formed of hafnium-aluminum oxide is compared with a case in which the charge trap layer is formed of silicon nitride (SiN). The hafnium-aluminum oxide is evenly dispersed in the charge trap layer. In other words, in the simulation, the charge trap layer does not have a structure in which the nanostructures 123b are isolated in the matrix 123a. In FIG. 5, “SiN” of an item “Trap” indicates a case in which silicon nitride is used as the charge trap layer. “V_{pgm} speed” indicates a voltage at which a program OFF state transitions to a program ON state. “V_{pgm} speed” indicates a program speed. The less the “V_{pgm} speed” is, the less the driving voltage required to turn on the transistor is low, and power consumption is small. “ISPP Max. Vth” indicates a voltage at which the transistor transitions from an ON state to an OFF state. “ISPP Max. Vth” indicates an erase speed. When “ISPP Max. Vth” is increased, a memory window is increased, so that storage capacity of the memory cell MC is increased. “0K 200C 2 hr Retention” indicates variance of a threshold voltage Vth after retention of 2 hours at 200° C. after program ON. “Lateral C/L” indicates a charge loss due to lateral migration of charges, and is calculated according to “Short Tr. C/L”-“Long Tr. C/L”. When “Lateral C/L” is small, it means that a charge retention performance is excellent.

Referring to FIG. 5, when content of hafnium (Hf) is 48%, “V_{pgm} speed” and “ISPP Max. Vth” are close to a case in which silicon nitride is used as the charge trap layer. Therefore, when content of Hf is equal to or greater than 50%, it is possible to obtain a write/erase speed and a large program window which are equal or excellent, compared to a case of using silicon nitride. However, when content of Hf is 48%, it is disadvantageous in “Lateral C/L”, compared to a case in which silicon nitride is used as the charge trap layer. This disadvantage may be compensated for with a structure, as in an embodiment, in which the charge trap layer 123 in which the nanostructures 123b are dispersed in the matrix 123a is used, and a composition ratio of the first metal oxide dielectric (AO) of the nanostructures 123b is higher than a composition ratio of the first metal oxide dielectric (AO) of the matrix 123a. That is, the nanostructures 123b may have an AO-rich state, and the matrix 123a may have a BO-rich state. Therefore, as described above, when a combination of the first metal oxide dielectric and the second metal oxide dielectric is expressed as A_{R}B_{1-R}O, the nanostructures 123b may satisfy 0.5<R<1. In addition, the nanostructures 123b may satisfy 0.8<R<1. In this case, the matrix 123a may satisfy 0.5>R, and furthermore, may satisfy 0.2>R.

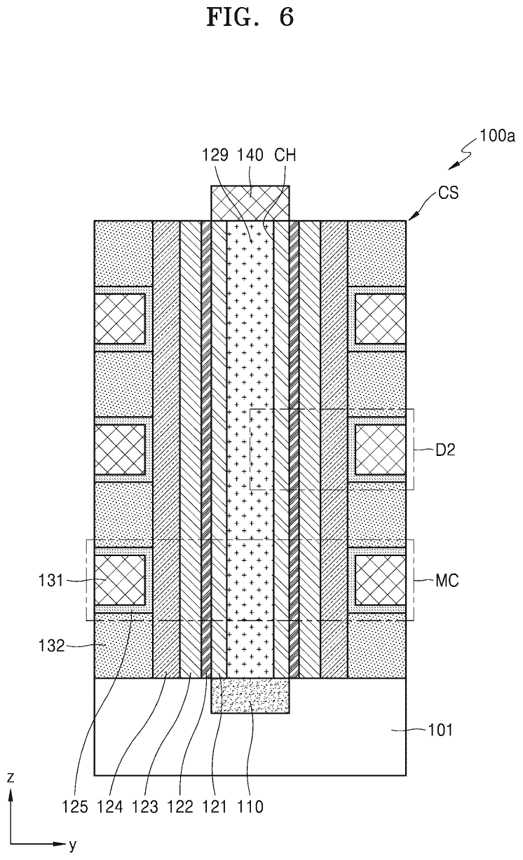

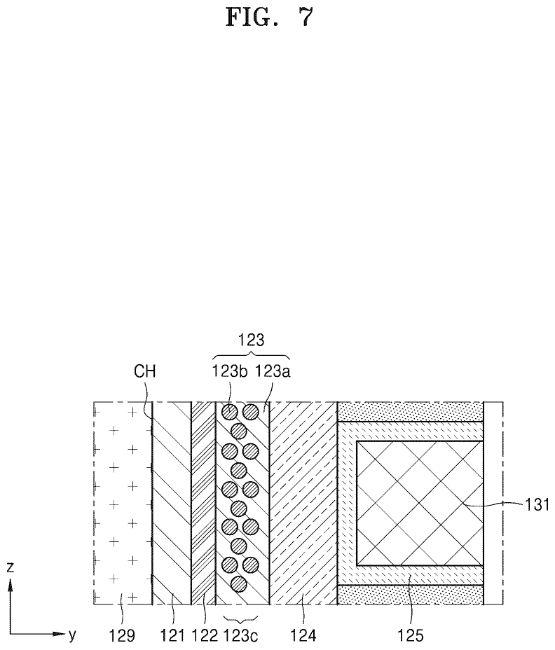

FIG. 6 is a schematic cross-sectional view of a vertical non-volatile memory device 100a (also referred to as the memory device 100a) according to an embodiment, and FIG. 7 is a magnified view of D2 portion of FIG. 6. The memory device 100a according to the present embodiment further includes a diffusion prevention layer 125, and thus, is different from the memory device 100 shown in FIGS. 1 to 3. Accordingly, descriptions of FIGS. 1 to 3 are applied to the memory device 100a shown in FIGS. 6 and 7, unless they are against properties. Hereinafter, same elements denote same reference numerals, redundant descriptions are omitted, and differences are mainly described.

Referring to FIGS. 6 and 7, the diffusion prevention layer 125 may be arranged between each gate electrode 131 and the charge blocking layer 124. The diffusion prevention layer 125 may be even arranged between each gate electrode 131 and each separation layer 132. The diffusion prevention layer 125 may prevent an interfacial reaction and atom diffusion between each gate electrode 131 and the charge trap layer 123. The diffusion prevention layer 125 may maximize adhesion of two adjacent material layers, for example, each gate electrode 131 and the charge blocking layer 124, and each gate electrode 131 and each separation layer 132. The diffusion prevention layer 125 may decrease an electric resistance at a contact surface between two material layers, thereby preventing power loss, temperature increase, and degradation of an operation characteristic of the memory device 100a. The diffusion prevention layer 125 may include a material having a greater redox potential than a material, e.g., silicon oxide, of each separation layer 132. The diffusion prevention layer 125 may include at least one of titanium (Ti), zirconium (Zr), vanadium (V), aluminum (Al), lanthanum (La), niobium (Nb), and tantalum (Ta), or may include nitride including at least one of them. For example, the diffusion prevention layer 125 may include TiN or NbN.

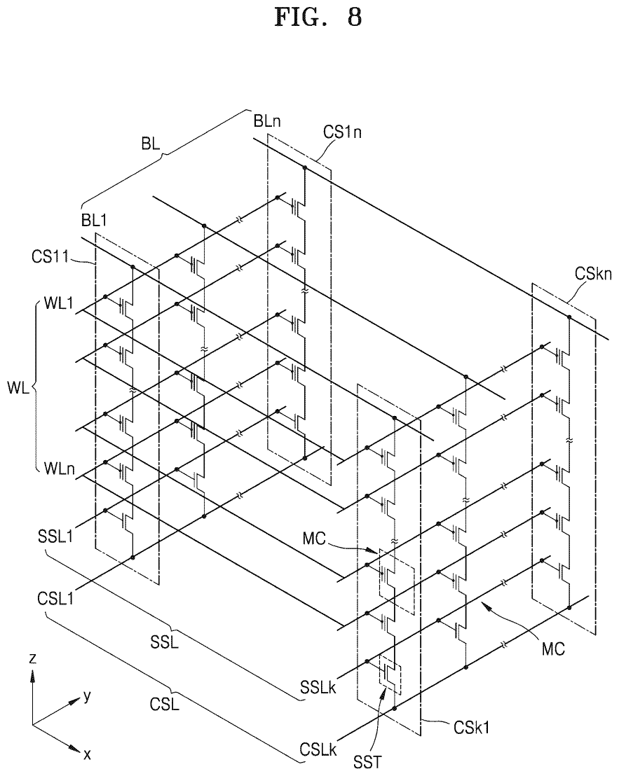

FIG. 8 illustrates a circuit diagram including a vertical non-volatile memory device according to an embodiment. k*n cell strings CS may be arranged in a matrix form, and may each be named as CSij(1≤i≤k, 1≤j≤n) according to locations of each row and column. Each cell string CSij may be connected to a bit line BL, a string selection line SSL, a word line WL, and a common source line CSL. Each cell string CSij includes memory cells MC and a string selection transistor SST. The memory cells MC and the string selection transistor SST of each cell string CSij may be stacked in a vertical direction.

Rows of the plurality of cell strings CS are respectively connected to different string selection lines SSL1 to SSLk. For example, string selection transistors SST of cell strings CS11 to CS1n are commonly connected to a string selection line SSL1. String selection transistors SST of cell strings CSk1 to CSkn are commonly connected to a string selection line SSLK.

Columns of the plurality of cell strings CS are respectively connected to different bit lines BL1 to BLn. For example, memory cells MC and string selection transistors SST of cell strings CS11 to CSk1 may be commonly connected to a bit line BL1, and memory cells MC and string selection transistors SST of cell strings CS1n to CSkn may be commonly connected to bit line BLn.

Rows of the plurality of cell strings CS may be respectively connected to different common source lines CSL1 to CSLk. For example, string selection transistors SST of cell strings CS11 to CS1n may be commonly connected to the common source line CSL1, and string selection transistors SST of cell strings CSK1 to CSkn may be commonly connected to the common source line CSLk.

Memory cells MC positioned at the same height from the substrate 101 or string selection transistors SST may be commonly connected to one word line WL, and memory cells MCs positioned at different heights may be respectively connected to different word lines WL1 to WLn.

The illustrated circuit structure is an example. For example, the number of rows of cell strings CS may be increased or decreased. When the number of rows of cell strings CS is changed, the number of string selection lines connected to the rows of the cell strings CS, and the number of cell strings CS connected to one bit line BL may also be changed. When the number of rows of cell strings CS is changed, the number of common source lines connected to the rows of the cell strings CS may also be changed.

The number of columns of cell strings CS may also be increased or decreased. When the number of columns of the cell strings CS is changed, the number of bit lines BL connected to the columns of the cell strings CS, and the number of cell strings CS connected to one string selection line may also be changed.

A height of each cell string CS may also be increased or decreased. For example, the number of memory cells MC stacked at each cell string CS may be increased or decreased. When the number of memory cells MCs stacked at each cell string CS is changed, the number of word lines WL may also be changed. For example, the number of string selection transistors provided for each cell string CS may be increased. When the number of string selection transistors provided for each cell string CS is changed, the number of string selection lines or common source lines may also be changed. When the number of string selection transistors SST is increased, the string selection transistors SST may be stacked in the same form as memory cells MCs.

For example, write and read may be performed in a unit of a row of cell strings CS. Cell strings CS may be selected in one unit of rows by a common source line CSL, and cell strings CS may be selected in one unit of row by string selection lines SSL. Also, with respect to common source lines CSL, a voltage may be applied to at least two common source lines CSL as one unit. Alternatively, a voltage may be applied to all common source lines CSL as one unit.

In a selected row of cell strings CS, write and read may be performed in a unit of page. The page may be one row of memory cells connected to one word line WL. In a selected row of cell strings CS, memory cells may be selected in a unit of page by word lines WL. For example, each gate electrode 131 of FIG. 1 may be connected to one of a word line WL and a string selection line SSL.

A memory cell MC has a circuit structure in which a transistor including each gate electrode 131, each separation layer 132, and the channel layer 121 is connected to the charge trap layer 123.

The memory cell MC is sequentially arranged in a perpendicular direction (z direction) to constitute a cell string CS. As shown in the circuit diagram of FIG. 8, both sides of the cell string CS may be connected to a common source line CSL and a bit line BL. As a voltage is applied to the common source line CSL and the bit line BL, a program, a read process, and an erase process may be performed on a plurality of memory cells MC.

For example, when a memory cell MC for a write operation is selected, a gate voltage value of the memory cell is adjusted so as not to form a channel in the selected memory cell, that is, the channel is to be off, and a gate voltage value of not-selected memory cells is adjusted to be channel-on in the not-selected memory cells. Accordingly, due to a voltage applied to the common source line CSL and the bit line BL, charges may be stored in the charge trap layer 123 of the selected memory cell MC by tunneling the charge tunneling layer 122, so that desired information of 1 or 0 may be written to the selected memory cell MC.

Similarly, in a read operation, read with respect to a selected cell may be performed. That is, after a gate voltage applied to each gate electrode 131 is adjusted to allow a selected memory cell MC to have a channel-off state and non-selected memory cells to have a channel-on state, current flowing in each memory cell MC due to an applied voltage Vread between a common source line CSL and a bit line BL may be measured to check a memory cell state (1 or 0).

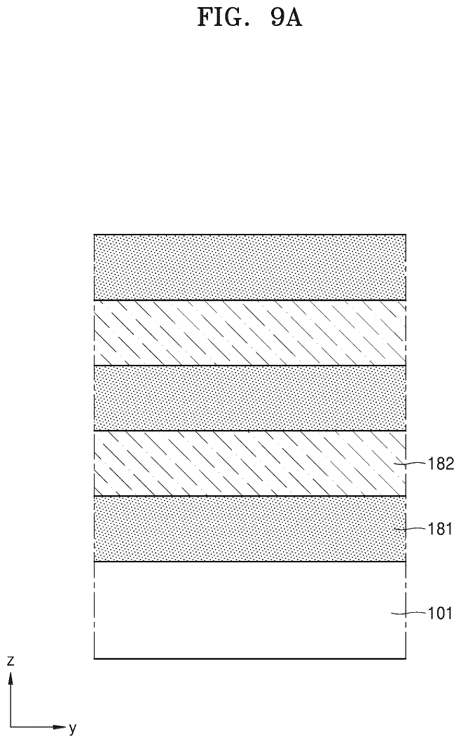

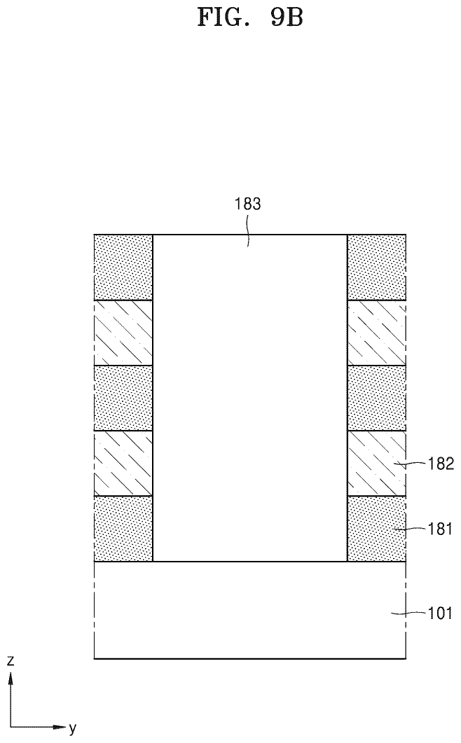

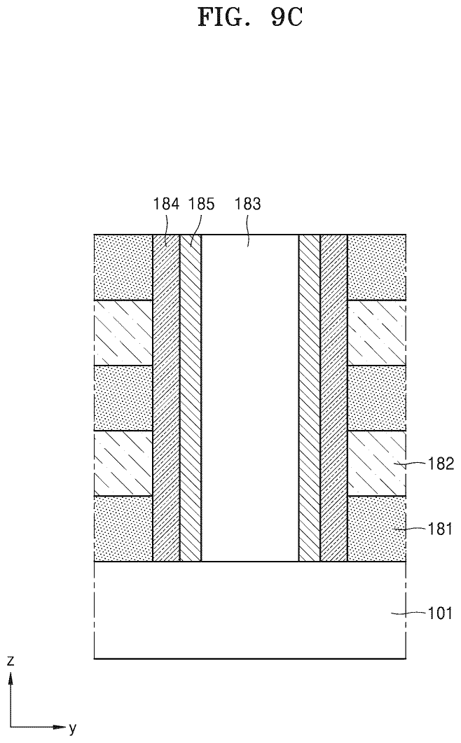

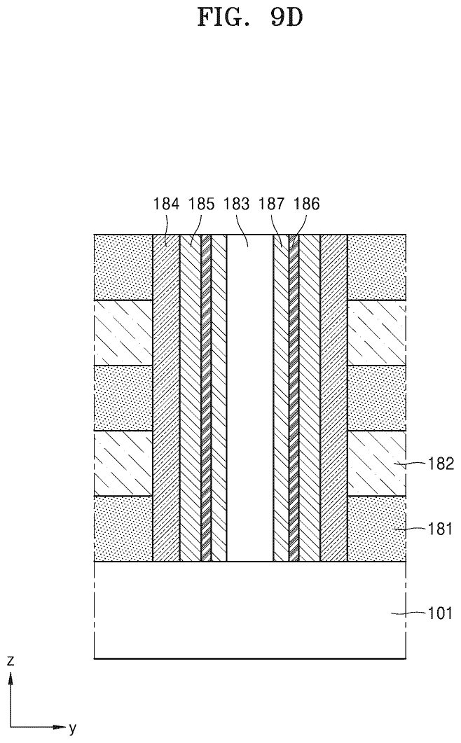

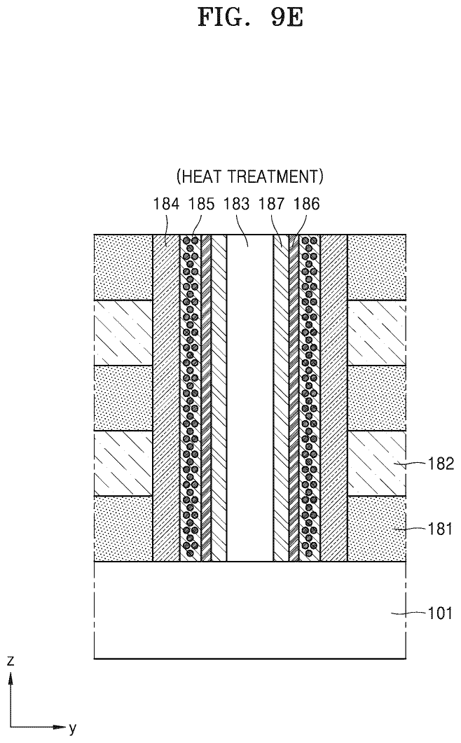

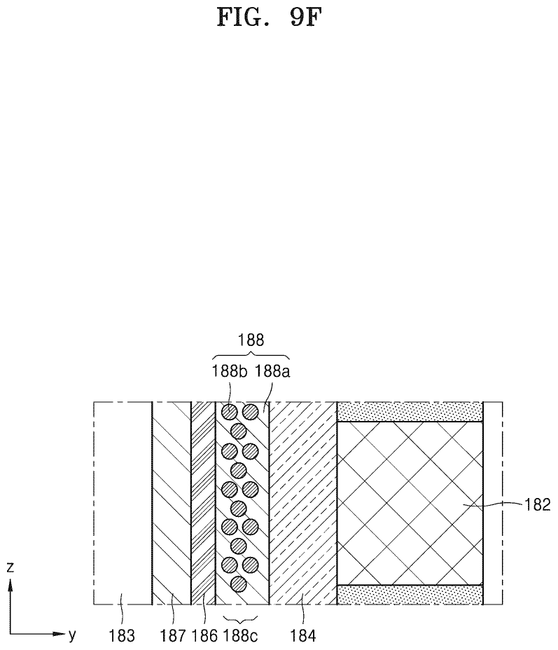

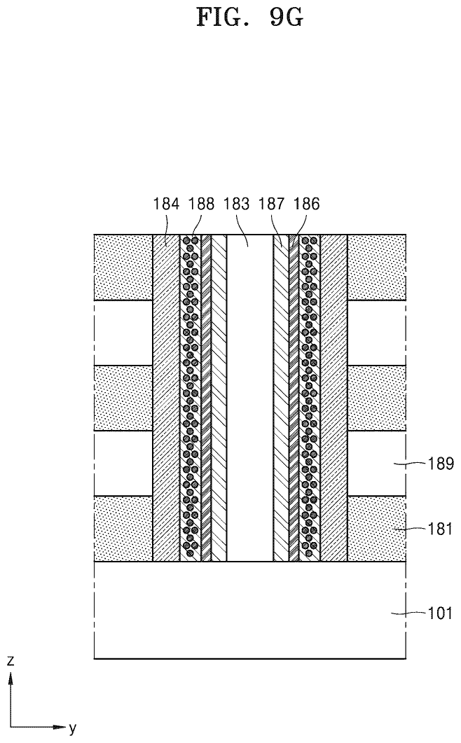

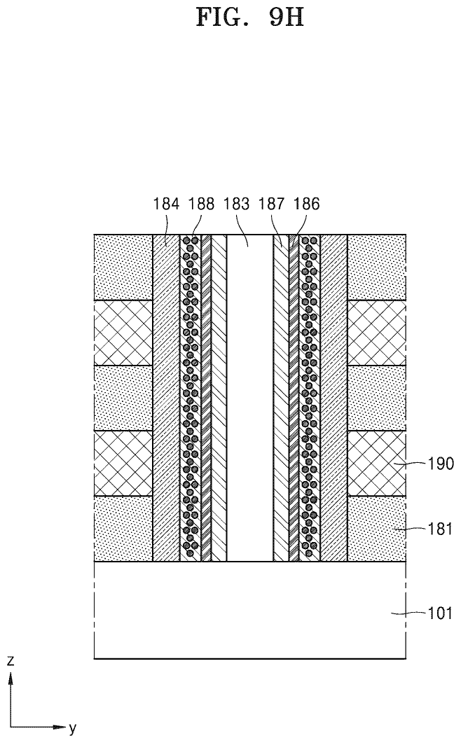

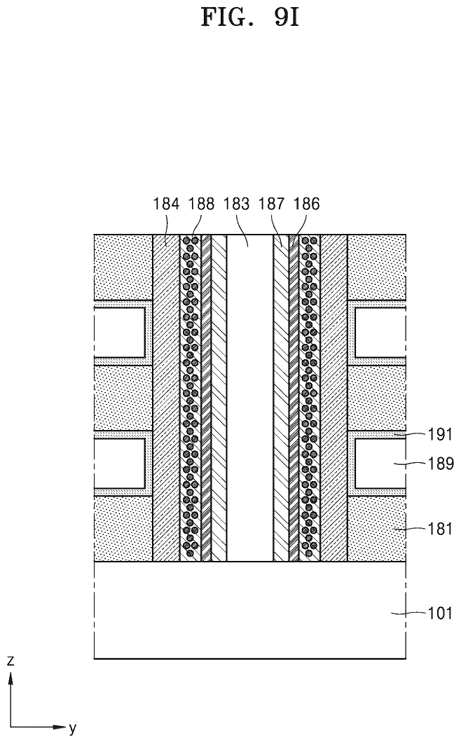

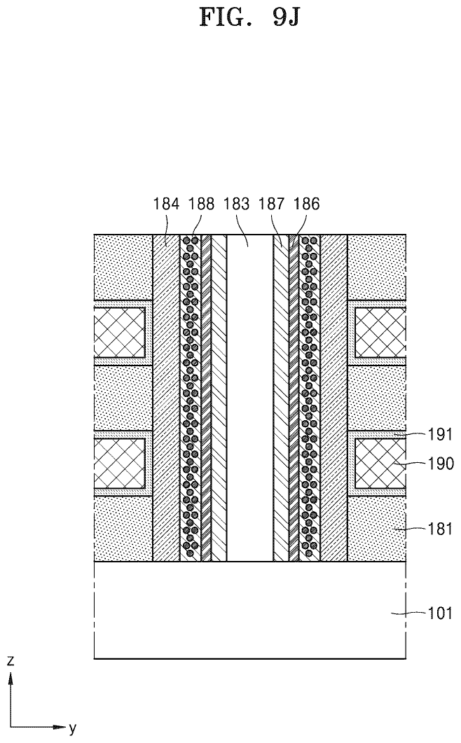

Hereinafter, embodiments of a method of manufacturing a vertical non-volatile memory device will now be described. FIGS. 9A to 9J illustrate an embodiment of a method of manufacturing a vertical non-volatile memory device.

First, referring to FIG. 9A, the substrate 101 is prepared. For example, the substrate 101 may include, but is not limited to, a single crystal silicon substrate, a compound semiconductor substrate, or a SOI. Also, the substrate 101 may further include an impurity-doped region, an electronic device such as a transistor, or a periphery circuit selecting and controlling memory cells for storing data.

Next, a first layer 181 and a second layer 182 are alternately stacked on the substrate 101. The first layer 181 may be an insulating layer. For example, the first layer 181 may include, but is not limited to, silicon oxide, silicon nitride, etc. The second layer 182 may be a conductive layer. For example, the second layer 182 may include, but is not limited to, a metal material, such as Au, having an excellent electric conductivity, or a silicon doped with impurities. For example, the first layer 181 and the second layer 182 may be formed by various deposition methods including chemical vapor deposition (CVD), atomic layer deposition (ALD), physical vapor deposition (PVD), etc.

Next, as shown in FIG. 9B, a channel hole 183 penetrating through the first layers 181 and the second layers 182 is formed. Here, the channel hole 183 may be formed to extend in a direction perpendicular to a top surface of the substrate 101. The channel hole 183 may extend to the top surface of the substrate 101. For example, the channel hole 183 may have a cylindrical shape, but is not limited thereto. The channel hole 183 may be formed by performing an anisotropic etching on the first layers 181 and the second layers 182.

Next, as shown in FIG. 9C, a charge blocking layer 184 is formed on an inner wall of the channel hole 183. The charge blocking layer 184 may be formed to extend in a direction perpendicular to a top surface of the substrate 101. The charge blocking layer 184 may be formed on the inner wall of the channel hole 183 so as to contact the first layer 181 and the second layer 182. The charge blocking layer 184 may be formed to have a cylindrical shape. The charge blocking layer 184 may be formed by depositing silicon oxide, metal oxide, or metal nitride on the inner wall of the channel hole 183 by using ALD.

Next, a combination layer 185 may be formed on an inner side of the charge blocking layer 184. The combination layer 185 is a layer in which the first metal oxide dielectric (AO) and the second metal oxide dielectric (BO) are mixed. The first metal oxide dielectric (AO) may be a material whose dielectric permittivity is higher than the second metal oxide dielectric (BO). A crystallization threshold energy of the first metal oxide dielectric (AO) may be lower than a crystallization threshold energy the second metal oxide dielectric (BO). The second metal oxide dielectric may be a material of which CBO and VBO with respect to a charge tunneling layer 186 are greater than the first metal oxide dielectric.

For example, the first metal oxide dielectric (AO) may include HfO, ZrO, LaO, GaO, YO, or TiO. For example, the second metal oxide dielectric (BO) may include AlO, TaO, or SiO.

The combination layer 185 may be formed by using thermal atomic layer deposition or plasma-enhanced atomic layer deposition. By using ALD, a first deposition cycle for depositing first metal oxide dielectric and a second deposition cycle for depositing a second metal oxide dielectric are repeatedly performed. A composition ratio of the first metal oxide dielectric and the second metal oxide dielectric in the combination layer 185 may be determined according to a relative performance ratio of the first deposition cycle to the second deposition cycle. A composition ratio of the first metal oxide dielectric and a composition ratio of the second metal oxide dielectric in a thickness direction of the combination layer 185 may be constant or may vary. For example, the composition ratio of the first metal oxide dielectric may be high in a center portion in the thickness direction of the combination layer 185, and the composition ratio of the second metal oxide dielectric may be high in both sides of the combination layer 185. The composition ratio of the first metal oxide dielectric and the composition ratio of the second metal oxide dielectric in the combination layer 185 and distribution of the composition ratios in the thickness direction of the combination layer 185 may be determined in such a manner that, in a matrix and nanostructures to be formed in a heat treatment process to be described below, the composition ratio of the first metal oxide dielectric satisfies 0.5<R<1 and further satisfies 0.8<R<1 in the nanostructures, and satisfies 0.5>R and further satisfies 0.2>R in the matrix. The combination layer 185 may have a meta-stable mixed phase.

Referring to FIG. 9D, the charge tunneling layer 186 is formed on a surface of the combination layer 185. The charge tunneling layer 186 may be formed by depositing silicon oxide or metal oxide on an inner wall of the combination layer 185 by using ALD. Afterward, a channel layer 187 is formed on a surface of the charge tunneling layer 186. The channel layer 187 may be formed by depositing a semiconductor material on an inner wall of the charge tunneling layer 186 by using ALD. Although not illustrated in FIG. 9D, the channel hole 183 may be filled by depositing a dielectric material such as silicon oxide on an inner side of the channel layer 187. However, the disclosure is not limited thereto, and the channel hole 183 may be filled with air.

Referring to FIGS. 9E and 9F, a structure shown in FIG. 9D is heat-treated at a particular temperature. The heat treatment temperature may be from about 800° C. to about 1300° C., and may be from about 900° C. to about 1100° C.

Spinodal decomposition occurs in the combination layer 185 due to the heat treatment process, and then, a nanostructures 188b are formed due to a nucleation growth. In other words, the combination layer 185 is a kind of solid solution, and due to thermodynamic instability of the solid solution, the nanostructures 188b having an AO-rich state, e.g., a high composition ratio of the first metal oxide dielectric, and a matrix 188a having a BO-rich state, e.g., a high composition ratio of the second metal oxide dielectric may be formed. The nanostructures 188b may have a diameter of about 3 nm to about 4 nm, and do not form an interface with the charge blocking layer 184 and the charge tunneling layer 186 which are adjacent thereto. The nanostructures 188b form an insertion layer 188c that is buried in the matrix 188a, and thus, is apart from the charge tunneling layer 186 and the charge blocking layer 184. Accordingly, each of the nanostructures 188b may function as independent charge trap media.

The nanostructures 188b may have various shapes including a round shape, an oval shape, a disc shape, a rod shape, an atypical shape, etc. A shape and size of the nanostructures 188b may be adjusted according to a heat treatment temperature. A shape, size, dispersion, etc. of the nano assemblies 188b may be identified via, for example, a transmission electron microscopy (TEM) analysis, an X-ray diffraction (XRD) analysis, or a photoluminescence (PL) analysis. A charge trap layer 188 may have an entirely amorphous structure. The first metal oxide dielectric having a low crystallization threshold energy provides a thermal stability by allowing the charge trap layer 188 to be amorphous in a high temperature by suppressing crystallization of the charge trap layer 188 in a heat treatment process of forming the charge trap layer 188. The matrix 188a may have an amorphous structure, and nanostructures 188b may have a crystalline or amorphous structure. When the nanostructures 188b have the crystalline structure, the nanostructures 188b may be referred to as nano crystals.

In the above description, a case in which the heat treatment process for spinodal decomposition is performed on a structure shown in FIG. 9D is described. However, the disclosure is not limited thereto, and the heat treatment process for spinodal decomposition may be performed in any operation after the combination layer 185 is formed in the manufacturing process.

The first layer 181 becomes a separation layer, and when the second layer 182 is a conductive layer, the second layer 182 becomes a gate electrode. The second layer 182 may not be the conductive layer. For example, the second layer 182 may be an insulating layer including an insulating material different from the first layer 181. In this case, an additional process may be performed to form a gate electrode. For example, a process of selectively removing the second layer 182 from a structure shown in FIG. 9E may be performed. Then, as shown in FIG. 9G, the opening 189 via which the charge blocking layer 184 is exposed is formed between the first layers 181. By filling a conductive material in the opening 189, as shown in FIG. 9H, the gate electrode 190 facing the channel layer 187 may be formed. By doing so, the memory device 100 shown in FIGS. 2 and 3 may be manufactured.

An embodiment of a method of manufacturing the memory device 100a shown in FIGS. 6 and 7 will now be described. First, processes of FIGS. 9A to 9G are performed. Next, a material having a greater higher redox potential than a material of the first layer 181, for example, silicon oxide, may be deposited on an outer surface of the charge blocking layer 184 exposed via the opening 189, and thus, a diffusion prevention layer 191 as shown in FIG. 9I may be formed. The diffusion prevention layer 191 may include at least one of Ti, Zr, V, Al, La, Nb, and Ta, or may include nitride including at least one of them. The diffusion prevention layer 191 may be formed on a surface of the first layer 181 exposed via the opening 189. Next, a conductive material is filled in the opening 189, so that the gate electrode 190 shown in FIG. 9J may be formed. By doing so, the memory device 100a shown in FIGS. 6 and 7 may be manufactured.

According to an embodiment, a vertical non-volatile memory device may be applied to various electronic devices.

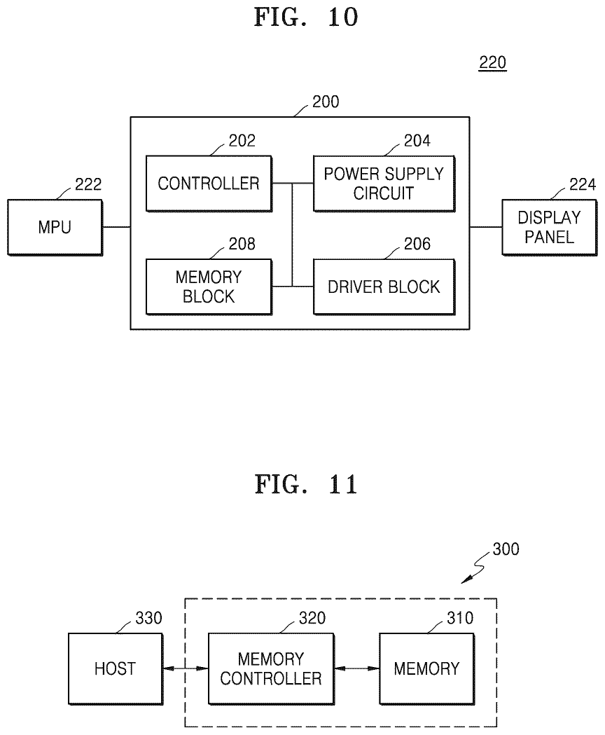

FIG. 10 is a schematic block diagram of a display driver integrated circuit (DDI) 200 and a display device 220 including the DDI 200, according to an embodiment. Referring to FIG. 10, the DDI 200 may include a controller 202, a power supply circuit 204, a driver block 206, and a memory block 208. The controller 202 may receive and decode a command applied from a main processing unit (MPU) 222, and controls each of blocks of the DDI 200 so as to implement an operation according to the command. The power supply circuit 204 generates a driving voltage, in response to the control by the controller 202. The driver block 206 drives the display panel 224 by using a driving voltage generated by the power supply circuit 204, in response to the control by the controller 202. For example, the display panel 224 may be a liquid crystal display panel, an organic light emitting device (OLED) display panel, or a plasma display panel. The memory block 208 may include a memory such as a random-access memory (RAM), a read-only memory (ROM), or the like, as a block for temporarily storing a command input to the controller 202 or control signals output from the controller 202, or storing a plurality of pieces of necessary data. For example, the memory block 208 may include the vertical non-volatile memory device 100 or 100a according to embodiments described above.

FIG. 11 is a block diagram illustrating an electronic device 300 according to an embodiment. Referring to FIG. 11, the electronic device 300 includes a memory 310 and a memory controller 320. The memory controller 320 may control the memory 310 so as to read data from the memory 310 and/or to write data to the memory 310, in response to a request from a host 330. The memory 310 may include the vertical non-volatile memory device 100 or 100a according to embodiments described above.

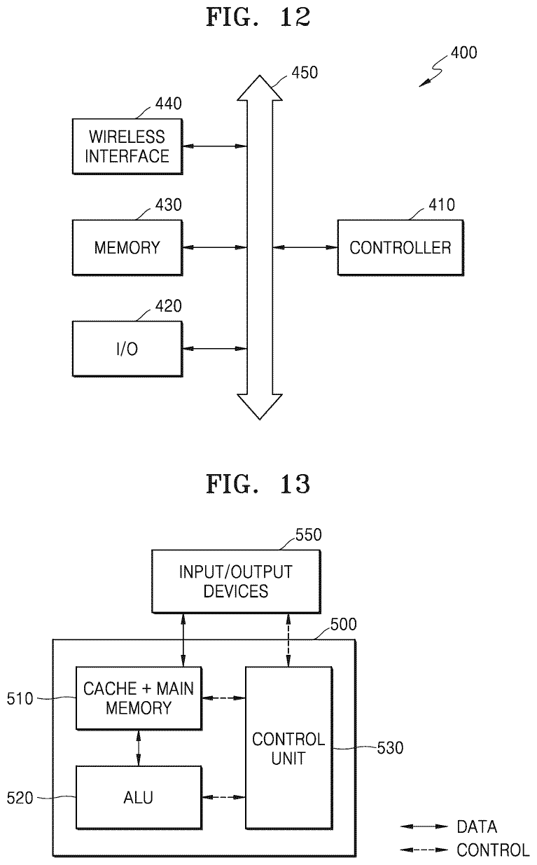

FIG. 12 is a block diagram of an electronic device 400 according to an embodiment. Referring to FIG. 12, the electronic device 400 may configure a wireless communication device, or a device capable of transmitting and/or receiving information in a wireless environment. The electronic device 400 includes a controller 410, an input/output (I/O) device 420, a memory 430, and a wireless interface 440 which are connected to each other via a bus 450.

The controller 410 may include at least one of a microprocessor, a digital signal processor, or a processing device similar thereto. The I/O device 420 may include at least one of a keypad, a keyboard, or a display. The memory 430 may be used to store a command executed by the controller 410. For example, the memory 430 may be used to store user data. The electronic device 400 may use the wireless interface 440 to transmit/receive data via a wireless communication network. The wireless interface 440 may include an antenna and/or a wireless transceiver. In some embodiments, the electronic device 400 may be used in a communication interface protocol of a 3^{rd}-generation communication system such as code division multiple access (CDMA), global system for mobile communications (GSM), North American digital cellular (NADC), extended-time division multiple access (E-TDMA) and/or wide band code division multiple access (WCDMA). The memory 430 of the electronic device 400 may include the vertical non-volatile memory device 100 or 100a according to embodiments described above.

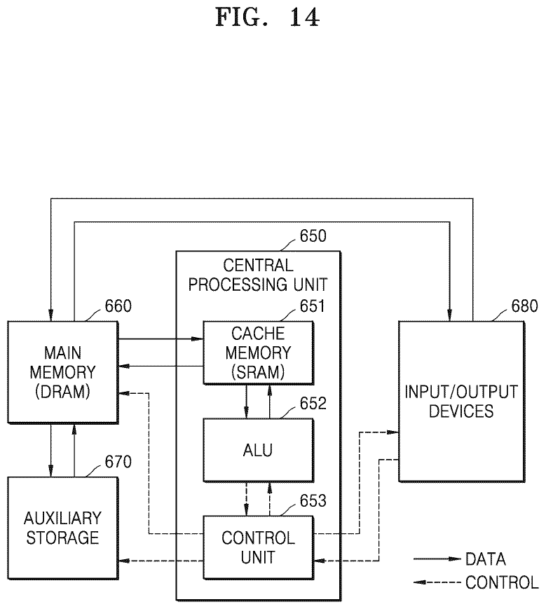

FIGS. 13 and 14 are conceptual diagram schematically illustrating device architecture applicable to an electronic device according to an embodiment.

Referring to FIG. 13, electronic device architecture 500 may include a memory unit 510 and a control unit 530, and may further include an arithmetic logic unit (ALU) 520. The memory unit 510, the ALU 520, and the control unit 530 may be electrically connected. For example, the electronic device architecture 500 may be implemented as one chip including the memory unit 510, the ALU 520, and the control unit 530. In detail, the memory unit 510, the ALU 520, and the control unit 530 may directly communicate by being connected to each other via a metal line on an on-chip. The memory unit 510, the ALU 520, and the control unit 530 may be monolithically integrated on one substrate (see the substrate 101 of FIG. 1) so as to configure one chip. An I/O device 550 (e.g., keyboard, display) may be connected to the electronic device architecture (chip) 500. Also, the memory unit 510 may include both a main memory and a cache memory. The electronic device architecture (chip) 500 may be an on-chip memory processing unit. The memory unit 510, the ALU 520, and the control unit 530 may independently include the vertical non-volatile memory device 100 according to embodiments described above.

Referring to FIG. 14, a cache memory 651, an ALU 652, and a control unit 653 may configure a central processing unit (CPU) 650, and the cache memory 651 may include a static random access memory (SRAM). Separately from the CPU 650, a main memory 660 and an auxiliary storage 670 may be arranged, and also, an I/O device 680 may be arranged. The main memory 660 may be a dynamic random access memory (DRAM), and may include the vertical non-volatile memory device 100 or 100a according to embodiments described above.

In some cases, the electronic device architecture may be implemented in a manner that computing unit devices and memory unit devices are adjacent to each other in one chip, without division of sub-units.

According to embodiments, a vertical non-volatile memory device may be applied to various user devices including a computer, a mobile computer, a ultra mobile personal computer (UMPC), a workstation, a net-book, a PDA, a portable computer, a web tablet, a wireless phone, a mobile phone, a smartphone, a digital camera, a digital audio recorder, a digital audio player, a digital picture recorder, a digital picture player, a digital video recorder, a digital video player, a device capable of transmitting and receiving information in a wireless environment, a home network, or the like.

While an embodiment has been described with reference to the drawings, it will be understood by one of ordinary skill in the art that various changes in form and details and equivalent embodiments may be made therein without departing from the spirit and scope as defined by the following claims. Although the details are specifically provided in the descriptions above, they are examples of particular embodiments rather than limiting the scope of the disclosure. Thus, the spirit and scope of the disclosure should be defined not by described embodiments but by the technical concept defined in the following claims.

In a memory device according to an embodiment, lateral migration of charges in a charge trap layer is limited and/or blocked due to a matrix-nanostructures structure, so that a higher charge retention characteristic may be ensured, and an operation characteristic of the memory device may be improved.

According to a method of manufacturing a vertical non-volatile memory device according to an embodiment, a charge trap layer of a matrix-nanostructures structure may be formed via a heat treatment.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A vertical non-volatile memory device comprising:
a plurality of cell strings, wherein
each of the plurality of cell strings comprises a channel layer, a charge tunneling layer, a charge trap layer, and a charge blocking layer, which are sequentially arranged in a horizontal direction,
the horizontal direction is perpendicular to a longitudinal direction,
each of the plurality of cell strings further comprises a plurality of gate electrodes, which are arranged in the longitudinal direction on an outer side of the charge blocking layer, and a plurality of separation layers isolating the plurality of gate electrodes in the longitudinal direction,
the charge trap layer comprises a film having a plurality of nanostructures dispersed in a matrix,
the charge trap layer comprises a first metal oxide dielectric and a second metal oxide dielectric,
a dielectric permittivity of the first metal oxide dielectric is greater than a dielectric permittivity of the second metal oxide dielectric, and
a composition ratio of the first metal oxide dielectric of the plurality of nanostructures is greater than a composition ratio of the first metal oxide dielectric of the matrix.

2. The memory device of claim 1, wherein the plurality of nanostructures are apart from each other.

3. The memory device of claim 1, wherein the plurality of nanostructures are apart from the charge tunneling layer and the charge blocking layer by the matrix.

4. The memory device of claim 1, wherein
the plurality of nanostructures define an insertion layer, and
the insertion layer is apart from the charge tunneling layer and the charge blocking layer by the matrix.

5. The memory device of claim 1, wherein the composition ratio of the first metal oxide dielectric of the plurality of nanostructures is greater than 50% and less than 100%.

6. The memory device of claim 1, wherein the composition ratio of the first metal oxide dielectric of the plurality of nanostructures is equal to or greater than 80% and less than 100%.

7. The memory device of claim 1, wherein a crystallization threshold energy of the first metal oxide dielectric is lower than a crystallization threshold energy of the second metal oxide dielectric.

8. The memory device of claim 1, wherein a conduction band offset of the second metal oxide dielectric with respect to the charge tunneling layer is greater than a conduction band offset of the first metal oxide dielectric with respect to the charge tunneling layer.

9. The memory device of claim 1, wherein the first metal oxide dielectric comprises hafnium oxide (HfO), zirconium oxide (ZrO), lanthanum oxide (LaO), gallium oxide (GaO), yttrium oxide (YO), or titanium oxide (TiO).

10. The memory device of claim 1, wherein the second metal oxide dielectric comprises aluminum oxide (AlO), tantalum oxide (TaO), or silicon oxide (SiO).

11. A method of manufacturing a memory device, the method comprising:
alternately stacking a first layer and a second layer on a substrate;
forming a channel hole penetrating through the first layer and the second layer; and
forming a charge blocking layer, a charge trap layer, a charge tunneling layer, and a channel layer sequentially from an inner wall of the channel hole,
wherein the forming the charge trap layer comprises
forming, on an inner wall of the charge blocking layer, a combination layer in which a first metal oxide dielectric having a relatively high dielectric permittivity and a second metal oxide dielectric having a relatively low dielectric permittivity are mixed, and
performing a heat treatment on the combination layer,
wherein the heat treatment on the combination layer forms a plurality of nanostructures in matrix, a composition ratio of the second metal oxide dielectric is higher in the matrix than in the plurality of nanostructures, a composition ratio of the first metal oxide dielectric is higher in the plurality of nanostructures than in the matrix.

12. The method of claim 11, wherein
the plurality of nanostructures are apart from each other, and
the plurality of nanostructures are apart from the charge tunneling layer and the charge blocking layer by the matrix.

13. The method of claim 11, wherein the composition ratio of the first metal oxide dielectric of the plurality of nanostructures is greater than 50% and less than 100%.

14. The method of claim 11, wherein the composition ratio of the first metal oxide dielectric of the plurality of nanostructures is equal to or greater than 80% and less than 100%.

15. The method of claim 11, wherein a crystallization threshold energy of the first metal oxide dielectric is lower than a crystallization threshold energy of the second metal oxide dielectric.

16. The method of claim 11, wherein a conduction band offset of the second metal oxide dielectric with respect to the charge tunneling layer is greater than a conduction band offset of the first metal oxide dielectric with respect to the charge tunneling layer.

17. The method of claim 11, wherein the first metal oxide dielectric comprises hafnium oxide (HfO), zirconium oxide (ZrO), lanthanum oxide (LaO), gallium oxide (GaO), yttrium oxide (YO), or titanium oxide (TiO).

18. The method of claim 11, wherein the second metal oxide dielectric comprises aluminum oxide (AlO), tantalum oxide (TaO), or silicon oxide (SiO).

19. An electronic device comprising:
a memory; and
a memory controller configured to control the memory,
wherein the memory comprises the memory device of claim 1.
